(19) United States
(12) Patent Application Publication
(10) Pub. No.: US 2009/0315072 A1
(43) Pub. Date: Dec. 24, 2009

(54) Semiconductor Device, Semiconductor Integrated Circuit Equipment Using the Same for Driving Plasma Display, and Plasma Display Unit

(75) Inventors: Shinji Shirakawa, Hitachi (JP); Junichi Sakano, Hitachi (JP); Kenji Hara, Hitachi (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi, Ltd., Tokyo (JP)

(21) Appl. No.: 12/487,299

(22) Filed: Jun. 18, 2009

(30) Foreign Application Priority Data
Jun. 20, 2008 (JP) 2008-161542

(51) Int. Cl. H01L 29/739

(52) U.S. Cl. 257/139; 257/88; 257/E29.197

(57) ABSTRACT

In a lateral IGBT structure equipped with an emitter terminal, comprising two or more second conductivity type base layers, per one collector terminal, the second conductivity type base layer in the emitter region is covered by a first conductivity type layer which has a higher impurity concentration than the drift layer, and width L1 of the gate electrode located between two adjacent emitters is 4 μm or less, or in addition to that, width L2 of the opening for leading out an emitter electrode located between two adjacent gate electrodes is 3 μm or less.

### CLAIM OF PRIORITY

The present application claims priority from Japanese patent application serial No. 2008-161542, filed on Jun. 20, 2008, the content of which is hereby incorporated by reference into this application

### FIELD OF THE INVENTION

The present invention relates to a semiconductor device, such as an insulated gate bipolar transistor (hereafter, referred to as IGBT) and the like, semiconductor integrated circuit equipment using the same for driving a plasma display, and a plasma display unit.

### BACKGROUND OF THE INVENTION

Recently, high-voltage power ICs using SOI substrates have been actively developed because the IC's device isolation region is small and the IC is free of parasitic transistors. A high-voltage power IC to which the present invention is mainly applied is intended for a semiconductor IC for driving a plasma display, and the withstand voltage is a 200V class. In developing those high-voltage power ICs, it is necessary to improve the output characteristics of the high-voltage output device which directly drives a load from the viewpoint of improving performance and reducing the chip size. However, in a lateral IGBT mainly used as an output device of a power IC that uses an SOI substrate, because an emitter gate region and a collector region are created on the same plane, the substantial conductive area is reduced resulting in the decrease of current capacity per area of the element. Further, in a lateral IGBT, because current component in the lateral direction of the element is large, there are problems in that latch-up easily occurs and the region where the element operates in a stable manner is narrow. In view of these problems, lateral IGBTs have been developed in which current capacity per unit area has been increased and the region where the element operates stably is wide.

In view of the increase in output of the lateral IGBT, an approach to reduce resistance between two adjacent emitters and increase output current density by increasing the width L1 of the gate electrode located between two adjacent emitters has been proposed, for example, in Japanese Patent 3,522,983.

On the other hand, the inventors of the present invention have applied for a patent with regard to the increase in output of the lateral IGBT as Japanese Patent Application No. 2007-108802. The lateral IGBT according to the patent application adopts a configuration shown in FIG. 9 in order to increase current density.

In FIG. 9, a p-base region 2 is selectively created on the surface layer of the n-type semiconductor substrate 1, two n-emitter regions 4 are created on a part of the surface layer of the p-base region 2, and a p-contact region 3 is created between the two n-emitter regions 4 so that the p-contact region 3 partially overlaps with the n-emitter regions 4. An n-buffer region 9 is selectively created on the surface exposed portion of the n-type substrate 1 on which a p-base region 2 has not been created, and a p-collector region 10 is created on the surface layer of the n-buffer region 9. And, a gate electrode 6 which is connected to the G terminal via a gate oxide film 5 is created on the surface of the channel region 14 on the surface layer of the p-base region 2. Further, an emitter electrode 7, which commonly comes in contact with the surface of the n-emitter region 4 and the p-contact region 3, is provided, a collector electrode 11 is provided on the surface of the p-collector region 10, and the emitter electrode 7 and the collector electrode 11 are connected to the E terminal and the C terminal, respectively. An oxide film 16 is embedded between an n-type substrate 1 and a support substrate 17 of the SOI substrate. The drawing shows the right half of the lateral IGBT with the drawing's left end a-a′ considered as the center.

This structure is characterized in that an n-layer 18 which has a higher impurity concentration than the n-type semiconductor substrate 1 is newly created so that the n-layer covers the p-base region located at a central portion of the element. In the IGBT, resistance of the silicon layer located between the newly added high-concentration first conductivity type layer 18 which covers the emitter region and the embedded oxide film 16 can be made low. By doing so, current can flow in the emitter gate region away from the collector region without increasing the voltage drop, thereby increasing current density when compared with conventional structures.

### SUMMARY OF THE INVENTION

However, in an IGBT configured as shown in FIG. 9, when the concentration of n-type impurities in the n-layer 18, which is higher than that in the n-type semiconductor substrate 1, exceeds a certain concentration, the withstand voltage rapidly drops, and therefore, the increase in current density by at least doubling the concentration will be limited.

It is an object of the present invention to provide a semiconductor device such as a lateral IGBT in which output current density is further increased.

In a first aspect of the present invention, a semiconductor device comprises, on the surface layer of one main surface of a first conductivity type semiconductor substrate, a second conductivity type base region including a first conductivity type emitter region selectively created inside, a gate electrode created on the second conductivity type base region with an insulating film interposed, and a second conductivity type collector region; the two or more second conductivity type base regions being located between the two adjacent second conductivity type collector regions, wherein a first conductivity type region which has a higher impurity concentration than the first conductivity type semiconductor substrate is created between the two or more second conductivity type base regions and under the second conductivity type base regions, and the width of the gate electrode which is created to connect the two adjacent second conductivity type base regions via the insulating film is made to be 4 μm or less.

In a preferred embodiment of the present invention, in a withstand-voltage 200V class lateral IGBT, the width of the gate electrode located between two adjacent emitters is made narrow in order to ease the electric field of the silicon region right below the gate electrode located between the two adjacent emitters which becomes the withstand-voltage yield point when the n-type impurity concentration in the high-concentration n-layer 18 exceeds a certain concentration.

In a preferred embodiment of the present invention, in addition to the above, the volume of the high-concentration first conductivity type layer surrounding the p-base region is reduced by decreasing the width of the opening for leading out an emitter electrode located between two adjacent gate electrodes.

In a specific embodiment, the width of the gate electrode located between two adjacent emitters is made to be 4 μm or less, or in addition to that, the width of the opening for leading out an emitter electrode located between two adjacent gate electrodes is made to be 3 μm or less.

According to a preferred embodiment of the present invention, in a semiconductor device, such as a lateral IGBT and the like, the impurity concentration in the high-concentration first conductivity type layer which maintains the withstand voltage can be increased, thereby further increasing the output current density.

According to a preferred embodiment of the present invention, n-impurities in the high-concentration n-region surrounding the p-base region can be reduced, and immobilization of the electric-potential distribution in the p-base region and the surrounding n-region due to depletion occurs at a lower voltage, which makes it possible to reduce the electric field in the silicon region right below the gate electrode.

In addition, by decreasing the width of the opening for leading out an emitter electrode located between two adjacent gate electrodes, the current pathway to the collector can be made short and the emitter region can be made small; therefore, an electric field can be more easily applied to a channel region away from the collector among a plurality of channel regions. Therefore, in addition to the effect of increasing the concentration of the high-concentration n-layer, it is possible to increase the output current density.

By increasing the current density of the lateral IGBT, it is possible to provide a semiconductor integrated circuit for driving a plasma display that requires a high withstand voltage and large current by using a smaller size chip.

Further, even when the output current density is to be increased by making the channel region small due to the suppression of thermal diffusion, the above-mentioned problems to be solved by the present invention will occur because the volume of the n-region that surrounds the p-base region is increased. The present invention is effective for solving the problems.

Other objects and features of the present invention will be clearly explained in the embodiments described below.

### BRIEF DESCRIPTION OF THE DRAWINGS

FIG. 1 is a cross-sectional configuration diagram showing a first embodiment of a semiconductor device according to the present invention.

FIG. 2 is an electric-potential distribution diagram of a semiconductor device according to the technology used to previously apply for a patent when the device is turned off.

FIG. 3 is an electric-potential distribution diagram of a semiconductor device according to the technology used to previously apply for a patent when the device is turned off in the case when the n-type impurity concentration in the high-concentration n-layer is increased until the withstand voltage drops.

FIG. 4 is a characteristic comparative diagram of a semiconductor device according to an embodiment of the present invention and a semiconductor device according to the technology used to previously apply for a patent.

FIG. 5 is a characteristic comparative diagram of semiconductor devices according to two embodiments of the present invention.

FIG. 6 is a configuration example of an output stage circuit of semiconductor integrated circuit equipment for driving a plasma display which uses a semiconductor device according to an embodiment of the present invention.

FIG. 7 is a configuration example of semiconductor integrated circuit equipment for driving a plasma display which uses a semiconductor device according to an embodiment of the present invention.

FIG. 8 is a configuration example of a plasma display unit which uses semiconductor integrated circuit equipment for driving a plasma display that uses a semiconductor device according to an embodiment of the present invention.

FIG. 9 is a cross-sectional configuration diagram showing a semiconductor device according to the technology used to previously apply for a patent.

### DESCRIPTION OF THE PREFERRED EMBODIMENTS

Hereafter, embodiments of the present invention which improve the performance of the lateral IGBT and corresponding output characteristics of the high-voltage power IC and the reduction of the chip size will be described in detail with reference to the attached drawings.

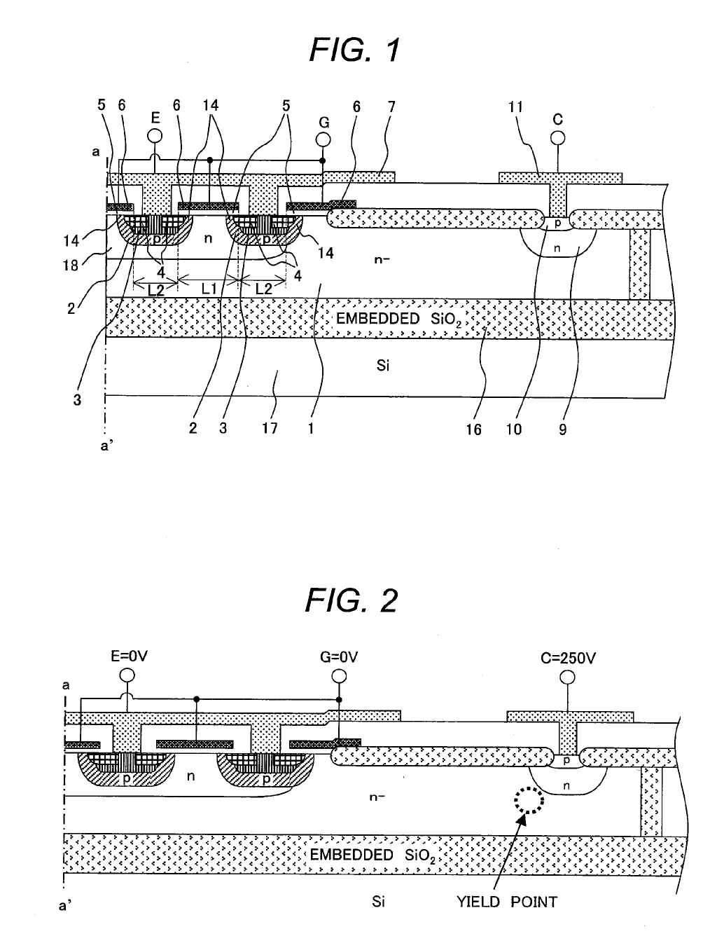

FIG. 1 is a partial cross-sectional configuration diagram showing an IGBT according to an embodiment of the present invention. The IGBT is configured such that the broken line a-a′ located at the left edge of the drawing is the central portion of the entire configuration and only the right half is shown in the drawing.

In FIG. 1, a p-base region 2 is selectively created on the surface layer of an n-type semiconductor substrate 1. Two n-emitter regions 4 are created on a part of the surface layer of a p-base region 2, and a p-contact region 3 is created between the two n-emitter regions 4 so that the p-contact region 3 partially overlaps with the n-emitter regions 4. An n-buffer region 9 is selectively created on a surface exposed portion of the n-type substrate 1 where p-base regions 2 are not created, and a p-collector region 10 is created on the surface layer of the n-buffer region 9. And, a gate electrode 6 connected to the gate (G) terminal via a gate oxide film 5 is provided on the surface of the channel region 14 of the surface layer of the p-base region 2. Further, an emitter electrode 7 which commonly comes in contact with the surface of both the n-emitter region 4 and the p-contact region 3 is provided, and a collector electrode 11 is provided on the surface of the p-collector region 10; and the emitter electrode 7 and the collector electrode 11 are connected to the emitter (E) terminal and the collector (C) terminal, respectively. An oxide film 16 is embedded between the n-type substrate 1 and the support substrate 17 of the SOI substrate. Further, an n-layer 18 which has a higher impurity concentration than the n-type semiconductor substrate 1 is newly created so that the n-layer covers the p-base region located in the central portion of the element. As shown in FIG. 1, there are a plurality of p-base regions 2, and those regions are separated by the n-type silicon region located below the gate electrode 6.

In this embodiment, width L1 of the gate electrode located between two adjacent emitters of the withstand-voltage 200V class IGBT is made to be 4 μm or less, or in addition to that, width L2 of the opening for leading out an emitter electrode between two adjacent gate electrodes is made to be 3 μm or less.

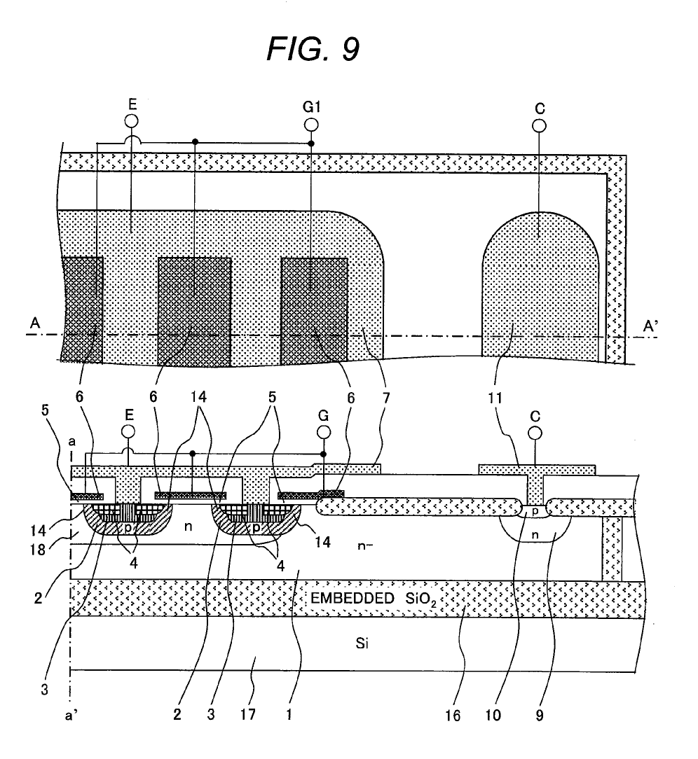

In the above-mentioned withstand-voltage 200V class lateral IGBT shown in FIG. 9, the phenomenon has been mentioned in which withstand voltage rapidly drops when the n-type impurity concentration in the high-concentration n-layer 18 exceeds a certain concentration. Results of the device simulation revealed that the yield point in the lateral IGBT is located in the silicon region right below the gate electrode located between two adjacent emitters.

FIG. 2 is an electric-potential distribution diagram of a semiconductor device, shown in FIG. 9, when the device is turned off; and the drawing shows the yield point when the withstand voltage has not dropped due to an n-type impurity concentration in the high-concentration n-layer 18. Herein, the yield point is shown when 0V is applied to the emitter and the gate, and 250V is applied to the collector. The yield point is where equipotential lines below the collector become dense (indicated by the circle plotted by a broken line in the drawing).

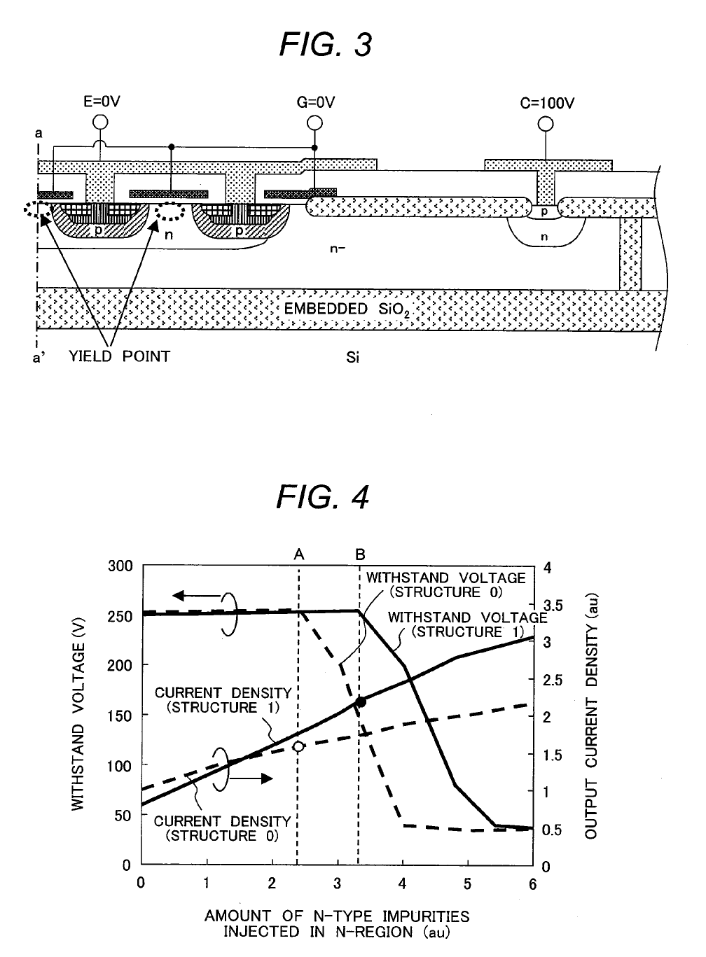

FIG. 3 is an electric-potential distribution diagram of a semiconductor device, shown in FIG. 9, when the device is off in the case when the n-type impurity concentration in the high-concentration n-layer 18 is increased until the withstand voltage drops; and the yield point is indicated. In FIG. 3, 0V is applied to the emitter and the gate, and 100V is applied to the collector; and because the electric field in the silicon region (indicated by the ellipse plotted by a broken line in the drawing) located right below the gate electrode located between two adjacent emitters becomes strongest, this portion becomes the yield point. The method of reducing the electric field in the silicon region located right below the gate electrode between the above-mentioned two adjacent emitters is to decrease the interval between the p-base regions 2 and make the portion between the p-base regions 2 become further recessed. That is, by decreasing the width of the gate electrode 6 located between two adjacent emitter electrodes, it is possible to reduce the fluctuation of electric potential of the region located between two adjacent p-base regions 2. Further, when positive voltage is applied to the collector from zero, the n-region that surrounds the p-base region 2 becomes depleted during a voltage rising process, and the electric-potential distribution of the p-base region 2 and the surrounding n-region is almost immobilized. The subsequent increment in collector voltage is to be applied mostly to the silicon region located between the p-base region 2 and the collector-side p-region 10. By immobilizing the electric-potential distribution of the above-mentioned p-base region 2 and the surrounding n-region 18 at a lower voltage, it is possible to reduce the electric field in the silicon region located right below the gate electrode between the above-mentioned two adjacent emitters.

To summarize the above embodiment, a semiconductor device comprises, on the surface layer of one main surface of a first conductivity type semiconductor substrate 1, a second conductivity type base region 2 including a first conductivity type emitter region 4 selectively created inside, a gate electrode 6 created on the second conductivity type base region 2 with an insulating film 5 interposed, and a second conductivity type collector region 10; the two or more second conductivity type base regions 2 being located between the two adjacent second conductivity type collector regions 10, wherein a first conductivity type region 18 which has a higher impurity concentration than the first conductivity type semiconductor substrate 1 is created between the two or more second conductivity type base regions 2 and under the second conductivity type base regions 2, and the width of the gate electrode 6 which is created to connect the two adjacent second conductivity type base regions 2 via the insulating film 5 is made to be 4 μm or less.

Further, in this embodiment, width L1 of the gate electrode located between two adjacent emitter electrodes is made narrow, and in addition to that, the width L2 of the opening for leading out an emitter electrode 7 located between two adjacent gate electrodes 6 is also made narrow. By doing so, the volume of the n-region that surrounds the p-base region 2 is reduced, and the amount of n-type impurities in the n-region that surrounds the p-base region 2 is reduced, which results in depletion at a lower collector voltage. As a result, it is possible to increase the n-type impurity concentration in the high-concentration n-layer 18 while the withstand voltage can be maintained, which makes it possible to increase the output current density.

FIG. 4 is a characteristic comparative diagram of a semiconductor device, shown in FIG. 9, and a semiconductor device according to an embodiment of the present invention. The diagram shows the results of a device simulation with regard to structure 0 in which L1=6 μm and L2=4 μm in the lateral IGBT, shown in FIG. 9, and structure 1 in which L1=4 μm and L2=4 μm in the lateral IGBT shown in FIG. 1. FIG. 4 shows a graph to compare the withstand voltage and output current density with regard to the above-mentioned structure 0 and structure 1 by plotting the concentration of n-type impurities, injected to create a high-concentration n-layer 18, as a variable (horizontal axis). The limit of the concentration of n-type impurities to maintain the withstand voltage in structure 0 is indicated by the broken line A, and the limit of the concentration of n-type impurities to maintain the withstand voltage in structure 1 is indicated by the broken line B. The intersections at which broken lines A and B intersect with corresponding output current density lines, respectively, are indicated by a white circle and a black circle.

As clearly shown in FIG. 4, by changing the structure of the lateral IGBT from structure 0 to structure 1, the concentration of n-type impurities that can maintain the withstand voltage is increased, thereby making it possible to increase the output current density from the value indicated by the white circle to the value indicated by the black circle.

Moreover, as disclosed in patent document 1, there is an idea in which increasing the width L1 of the gate electrode located between two adjacent emitters will decrease the resistance between the two adjacent emitters and increase the output current density. However, in an IGBT equipped with a high-concentration n-layer 18, from the aspect of improving the trade-off point between the withstand voltage and output current performance, in an embodiment of the present invention, the width L1 of the gate electrode located between two adjacent emitter electrodes and the width L2 of the opening for leading out an emitter electrode located between two adjacent gate electrodes is decreased.

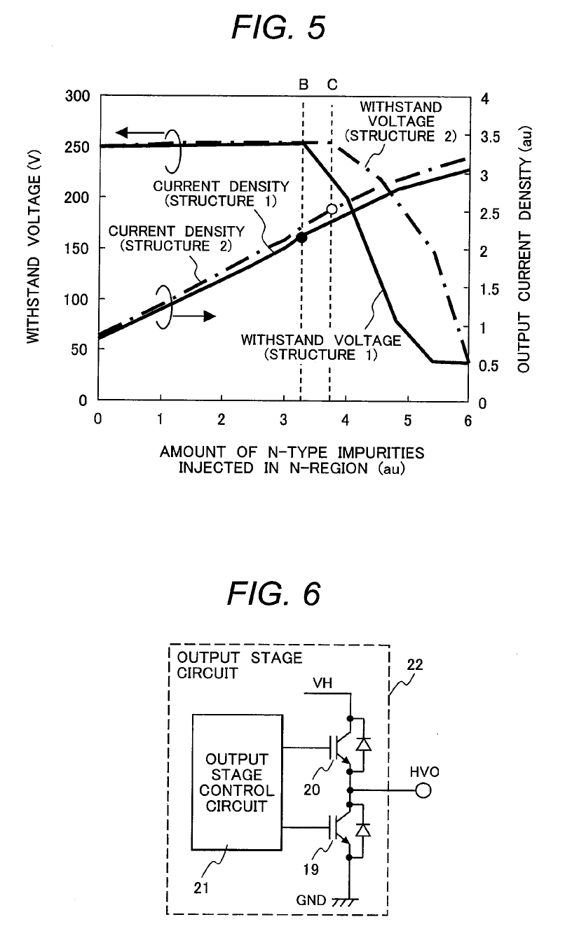

FIG. 5 is a characteristic comparative diagram of semiconductor devices according to two embodiments of the present invention. Herein, the amount of n-type impurities in the n-region that surrounds the p-base region 2 was reduced by reducing the volume of the n-region that surrounds the p-base region 2. Results of a device simulation by using this method with regard to structure 2 (L1=4 μm, L2=3 μm) in which the width L1 of the gate electrode is reduced and, in addition, the width L2 of the opening for leading out an emitter electrode located between two adjacent gate electrodes is also reduced are compared with the results of structure 1.

By using structure 2 in the same manner as the description of FIG. 4 in which both widths L1 and L2 are reduced, the limit of an n-type impurity concentration that can maintain the withstand voltage can be increased from the broken line B to the broken line C, and the output current density can be increased from the value indicated by the black circle to the value indicated by the white circle.

In comparison with structure 0 and structure 1 by using FIG. 4 and FIG. 5, the output current density has been increased by approximately 40%; and in comparison with structure 0 and structure 2, the output current density has been increased by approximately 60%. Further, when compared with the case in which additional n-type impurities are not included in the n-region, the output current density has at least doubled.

Thus, by increasing the current density of the lateral IGBT, it is possible to provide a semiconductor integrated circuit for driving a plasma display that requires a high withstand voltage and large current by using a smaller size chip.

FIG. 6 is a configuration example of an output stage circuit of semiconductor integrated circuit equipment for driving a plasma display which uses lateral IGBTs according to an embodiment of the present invention. The output stage circuit 22 is configured such that IGBTs 19 and 20 according to an embodiment of the present invention are connected in a totem-pole style between the power source VH and ground GND, and the connection point between the IGBTs 19 and 20 is output terminal HVO. IGBTs 19 and 20 can be turned on and off by the output stage control circuit 21, and the output terminal HVO is on the VH or GND voltage level or in the high-impedance state.

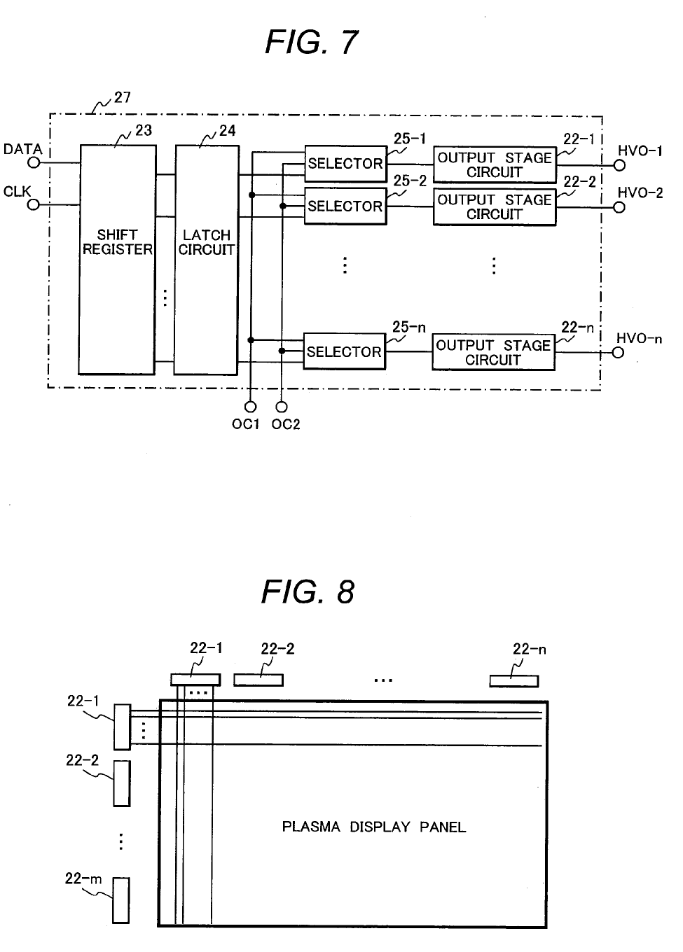

FIG. 7 is a configuration example of semiconductor integrated circuit equipment for driving a plasma display which uses a lateral IGBT according to an embodiment of the present invention. The semiconductor integrated circuit equipment for driving a plasma display 27 comprises a shift register circuit 23, latch circuit 24, selector 25, and an output stage circuit 26. The shift register circuit synchronizes the control signal inputted from terminal DATA with the clock signal inputted into terminal CLK and then shifts the signal. Further, in combination with terminals OC1 and OC2 connected to the selector, all of the output terminals are on the VH level, on the GND voltage level, in the high-impedance state, and in the data output state from the latch circuit.

FIG. 8 is a configuration example of a plasma display unit which uses semiconductor integrated circuit equipment for driving a plasma display that uses a semiconductor device according to an embodiment of the present invention. By configuring the circuit as shown in FIG. 8, it is possible to control the light-emitting portion of the plasma display unit. The use of the semiconductor integrated circuit equipment according to an embodiment of the present invention will enable the costs of the plasma display unit to be reduced.

1. A semiconductor device comprising, on the surface layer of one main surface of a first conductivity type semiconductor substrate,
a second conductivity type base region including a first conductivity type emitter region selectively created inside,
a gate electrode created on said second conductivity type base region with an insulating film interposed, and
a second conductivity type collector region;
said two or more second conductivity type base regions being located between said two adjacent second conductivity type collector regions, wherein
a first conductivity type region which has higher a impurity concentration than said first conductivity type semiconductor substrate is created between said two or more second conductivity type base regions and under said second conductivity type base regions, and the width of the gate electrode which is created to connect said two adjacent second conductivity type base regions via said insulating film is 4 μm or less.

2. The semiconductor device according to claim 1, wherein an emitter electrode is led out from the opening between said two adjacent gate electrodes, and the width of said opening between said two adjacent gate electrodes is 3 μm or less.

3. Semiconductor integrated circuit equipment for driving a plasma display using the semiconductor device according to claim 1.

4. A plasma display unit using the semiconductor integrated circuit equipment for driving a plasma display according to claim 3.
